(19) United States
(12) Patent Application Publication
(10) Pub. No.: US 2005/0206281 A1
(43) Pub. Date: Sep. 22, 2005

(54) Positioning structure for clasping computer front panel

(76) Inventor: Yu Wen-Lung, Taipei (TW)

Correspondence Address: Yi-Wen Tseng, 4331 Stevens Battle Lane, Fairfax, VA, 22033, US

(21) Appl. No.: 10/803,923

(22) Filed: Mar. 19, 2004

(51) Int. Cl. H05K 5/00

(52) U.S. Cl. 312/265.5; 312/223.2

(57) ABSTRACT

A positioning structure for clasping computer front panel, mainly comprising a front panel and a computer case, is disclosed. The front panel includes a rectangular casing body provided with two first vertical fasteners and two second horizontal fasteners extending backward from the rear side of this casing body, respectively. Moreover, locking grooves corresponding to the fasteners are openly provided on a front plate of the computer case to provide a mounting connection for the fasteners of the front panel. Thereby, a multi-directional positioning structure of the front panel for the improvement of mounting easiness and fastening reliability thereof is achieved by means of the fastening of the fasteners, provided on the front panel, into the locking grooves, provided on the computer case.

### FIELD OF THE INVENTION

The present invention is related to a positioning structure for clasping computer front panel, particularly to a multi-directional positioning structure for the front panel, allowed for the improvement of mounting easiness and fastening reliability of the panel.

### BACKGROUND

Accompanying with the active development and advancement in information technology, a more “light, thin, short, small” design has become the mainstream in the computer-related field. Especially for a miniaturized computer case, not only an ample and comfortable working space may be thus provided for a user, but also a merit of mobility inherent to the notebook is obtained. The reliability of the overall structure, however, should be emphasized specifically, owing to this feature of mobility. Therefore, a multi-directional positioning structure for front panel is an essential study topic for researchers in this field.

As illustrated in FIG. 1, there is shown a conventional fastening structure for computer front panel, comprising a front panel 10a and a computer case 20a. The front panel 10a includes a rectangular casing body 11a having two sets of corresponding resilient fasteners 12a (not shown) which, presented as vertical or horizontal mode, may extend backward from the rear side of the casing body 11a. Additionally, at the front panel of the computer case 20a, locking grooves 21a are openly provided in correspondence with the resilient fasteners 12a, in such a way that the fastening connection may be provided for the resilient fasteners 12a on the front panel 10a by the locking grooves 21a. Thereby, a fastening structure for computer front panel may be formed. In spite of the effect of fastening connection, in principle, there is still a problem as follows: A vertical sway of the front panel 10a generated when the resilient fasteners 12a are fastenedly connected into the locking grooves 21a of the computer case 20a, if the former are presented as a vertical mode; moreover, a horizontal sway of the front panel 10a generated when the resilient fasteners 12a are fastenedly connected into the locking grooves 21a of the computer case 20a, if the former are presented as a horizontal mode, may take place, due to a large clearance reserved for assembly for the sake of the improvement of the mounting easiness between the resilient fasteners 12a and the locking grooves 21a, as well as the consideration for the manufacturing tolerance. Thereby, the assembly reliability may be reduced significantly.

Thus, it can be seen that there apparently exist some inconveniences and problems to be eliminated in the practical use of the aforementioned conventional fastening structure for computer front panel.

Accordingly, in view of aforementioned problems and based on long-term experience in this field, the inventor has been finally set forth the present invention with the conscientious study cooperating with practical application and the spirit of keeping improvement, for aiming at the inconveniences and problems to be eliminated, so as to be designed reasonably and allowed for the effective elimination of the aforementioned problems.

### SUMMARY OF THE INVENTION

It is a primary object of the present invention to provide a positioning structure for clasping a computer front panel, the front panel having two first vertical fasteners and two second horizontal fasteners used for securely fastening into locking grooves of a computer case in order to form a positioning structure in horizontal and vertical directions, whereby a positioning structure for clasping panel with mounting easiness and fastening reliability is thus achieved.

For the purpose of achieving the aforementioned object, the present invention provides a positioning structure for clasping computer front panel mainly comprising a front panel and a computer case, in which the front panel includes a rectangular casing body provided with two first vertical fasteners and two second horizontal fasteners extending backward from the rear side of this casing body, respectively; moreover, locking grooves corresponding to the fasteners are openly provided on a front plate of the computer case to provide a mounting connection for the fasteners of the front panel, resulting in obtaining the aforementioned object.

### BRIEF DESCRIPTION OF DRAWINGS

FIG. 1 is an assembly diagram of a conventional computer case and a front panel;

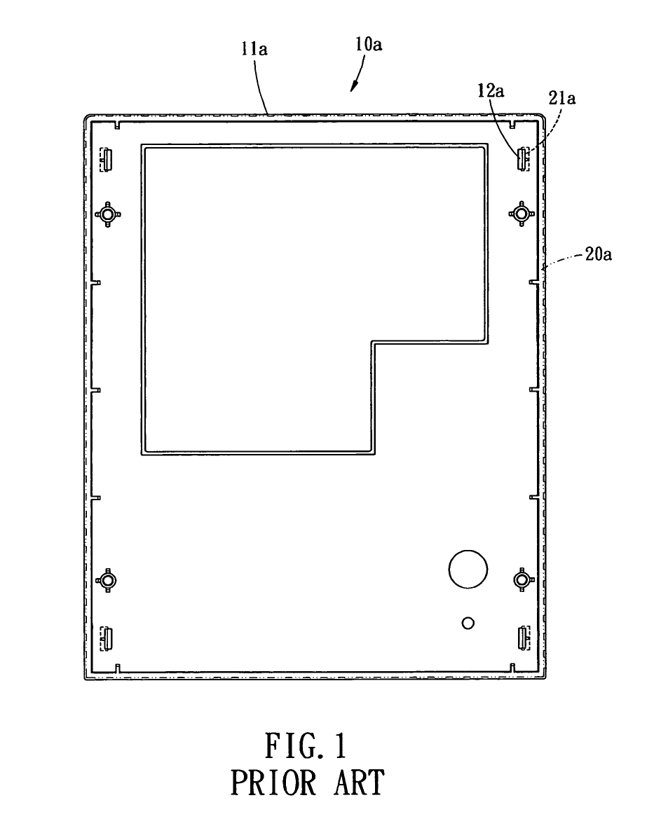

FIG. 2 is a rear perspective view of a front panel according to the present invention;

FIG. 3 is an exploded perspective view of a computer case and a front panel according to the present invention; and

FIG. 4 is an assembly diagram of the computer case and the front panel according to the present invention.

### DETAILED DESCRIPTION

The structural features and the effects to be achieved may further be understood and appreciated by reference to the following description together with the accompanying drawings, given purely by way of example and not considered as restrictive.

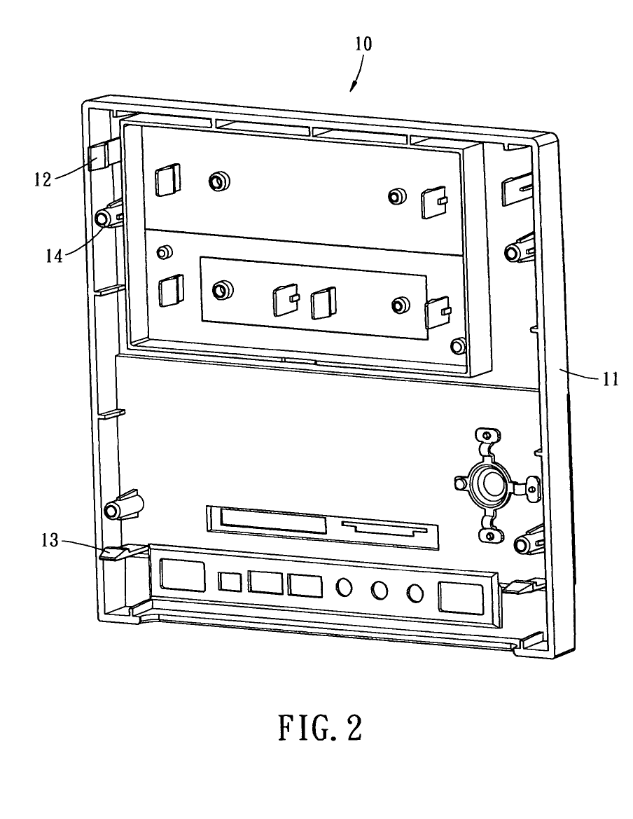

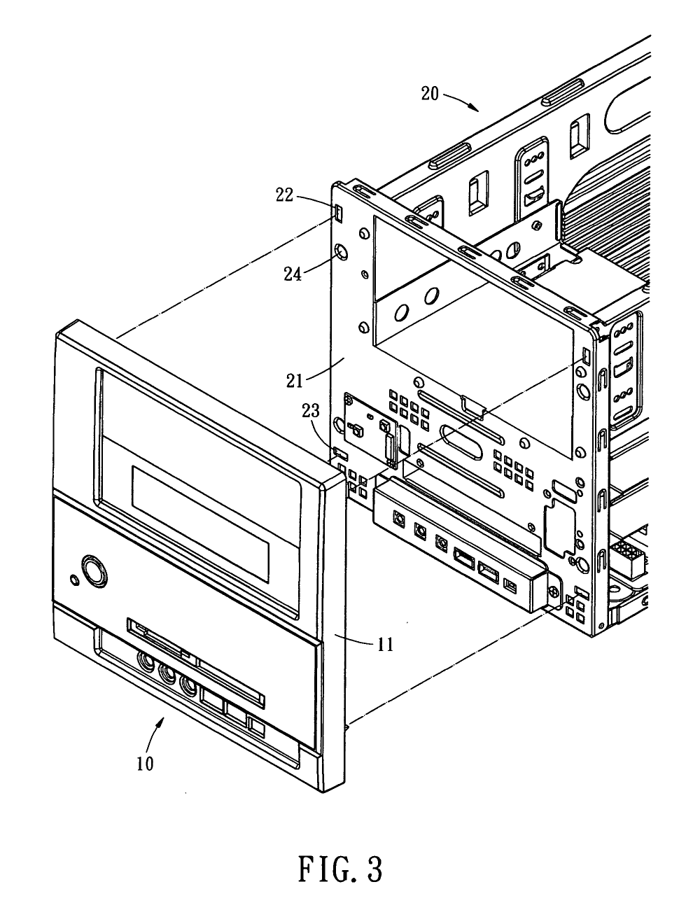

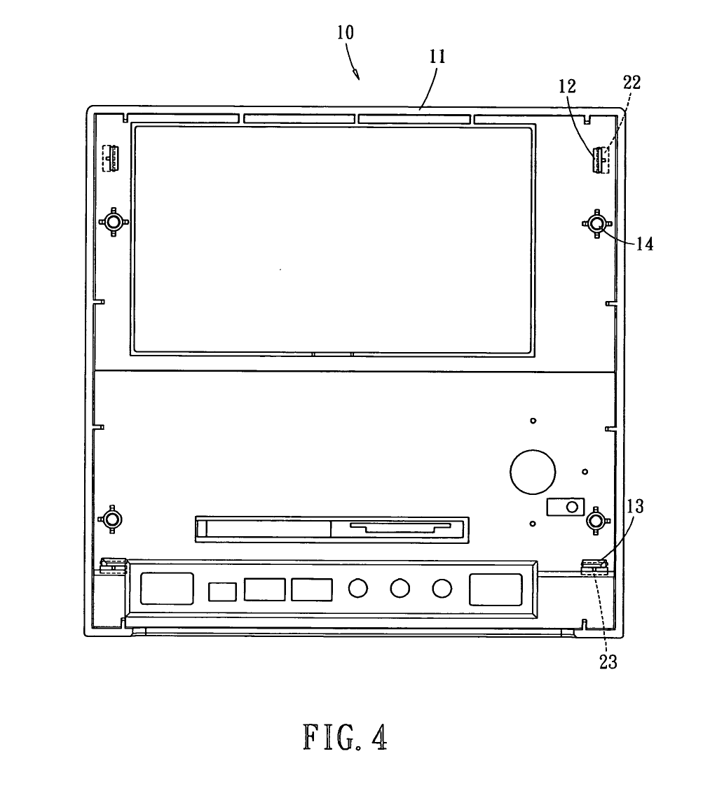

Referring to FIGS. 2, 3, and 4, there are shown a rear perspective view of a front panel, an exploded perspective view and an assembly diagram of a computer case and the front panel, respectively. The present invention provides a positioning structure for clasping computer front panel, mainly comprising a front panel 10 and a computer case 20, in which:

The front panel 10 of the present invention may be made from plastic or aluminum alloyed metal, etc., and provided with a casing body 11. At the upper end of the casing body 11, two first vertical fasteners 12 are provided extendingly backward, while at the lower end thereof, two second horizontal fasteners 13 are provided. Moreover, a plurality of circle positioning posts 14 are extendingly provided between the first fasteners 12 and the second fasteners 13 so as to be the guidance when assembling.

The computer case 20 of the present invention is a hollow frame installed therein with various electronic components, such as photo drives, hard disk drives, floppy drives, power indicating lights, power switches, etc. The installation of various circuit boards and other accessories of electronic products in the aforementioned structure may be identical to that in the conventional art, and may not be concerned with the claimed scope of the present invention, without the need for any detail.

Additionally, in the just front of the computer case 20, there is provided with a front plate 21, which is in turn openly provided with first locking grooves 22 corresponding to the first fasteners 12, and second locking grooves 23 corresponding to the second fasteners 13. Theses first locking grooves 22 and the second locking grooves 23 are used to provide a fastening connection for the first fasteners 12 and the second fasteners 13 of the front panel 10, respectively.

When assembling, the front panel 10 is inclined forward for fastening the second fasteners 13 of the front panel 10 into the second locking grooves 22 of the computer case 20, and then moving the front panel 10 upward by rotating it pivoted on the second fasteners 13. As such, the positioning posts 14 and the first fasteners 12 of the front panel 10 may be fastened into through-holes 24 and the first locking grooves 22 of the computer case 20 in turn, whereby a positioning structure for clasping panel with mounting easiness and fastening reliability may be formed.

As described above, a positioning structure for clasping computer front panel according to the present invention at least comprises numerous advantages as follows:

1. A multi-directional positioning structure is formed, due to the fact that the first fasteners and the second fasteners of the front panel of the present invention are disposed perpendicularly with each other so as to be securely fastened into the locking grooves of the computer case.

2. An installation with mounting easiness and fastening reliability is obtained, because the second fasteners of the front panel of the present invention are located at the lower portion to be the pivot, while the first fasteners thereof are presented as vertical mode so as to enter into the locking grooves just in the rotation direction of the front panel.

3. An increased easiness for the manufacture of components and a significantly reduced cost for the manufacture and assembly are achieved, owing to an enlarged permissible fit tolerance between the fasteners and the locking grooves, provided by the positioning structure for clasping front panel designed in accordance with the present invention.

To sum up, it should be understood that the positioning structure for clasping computer front panel is filed in accordance with the patent law duly, since the present invention is truly an invention with novelty, advancement or non-obviousness, and availability by the industry, thus naturally satisfying the requirements of patentability. Your favorable consideration will be appreciated.

The foregoing description is merely one embodiment of present invention and not considered as restrictive. All equivalent variations and modifications in process, method, feature, and spirit in accordance with the appended claims may be made without in any way from the scope of the invention.

1. A positioning structure for clasping computer front panel comprising a front panel and a computer case, wherein said front panel includes a casing body provided with two first vertical fasteners and two second horizontal fasteners extending backward from the rear side of said casing body, respectively; moreover, locking grooves corresponding to said fasteners are openly provided on a front plate of said computer case to provide a mounting connection for said fasteners of said front panel.

2. The positioning structure for clasping computer front panel according to claim 1, wherein said casing body of said front panel is presented as a flat rectangular mode.

3. The positioning structure for clasping computer front panel according to claim 1, wherein said casing body of said front panel is made from plastic or aluminum alloyed metal.

4. The positioning structure for clasping computer front panel according to claim 1, wherein said first fasteners of said front panel are provided on the upper end of said casing body.

5. The positioning structure for clasping computer front panel according to claim 1, wherein said second fasteners of said front panel are provided on the lower end of said casing body.

6. The positioning structure for clasping computer front panel according to claim 1, wherein a plurality of positioning posts are extendingly provided between said first fasteners and said second fasteners, said positioning posts having the effect of guidance when assembling.
